(19) United States
(12) Patent Application Publication
(10) Pub. No.: US 2016/0300823 A1
(43) Pub. Date: Oct. 13, 2016

(54) PACKAGE-ON-PACKAGE OPTIONS WITH MULTIPLE LAYER 3-D STACKING

(71) Applicant: Apple Inc., Cupertino, CA (US)

(72) Inventors: Jun Zhai, San Jose, CA (US); Kunzhong Hu, Cupertino, CA (US); Chonghua Zhong, Cupertino, CA (US)

(21) Appl. No.: 15/184,554

(22) Filed: Jun. 16, 2016

Related U.S. Application Data
(62) Division of application No. 14/541,228, filed on Nov. 14, 2014.
(60) Provisional application No. 62/024,147, filed on Jul. 14, 2014.

(51) Int. Cl. H01L 25/10; H01L 25/00

(52) U.S. Cl. CPC H01L 25/105; H01L 25/50; H01L 2225/1058

(57) ABSTRACT

In some embodiments, a semiconductor device package on package assembly may include a first package, a second package, and a third package. The first package may include a first surface, a second surface, a first die, and a first set of electrical conductors. The first set of electrical conductors may be configured to electrically connect the package on package assembly. The second package may include a third surface and a fourth surface, and a local memory module. The third surface may be coupled to the second surface. The first package may be electrically coupled to the second package. The third package may include a fifth surface and a sixth surface, and a main memory module. The fifth surface may be coupled to the fourth surface. The third package may be electrically coupled to the first package and/or the second package.

### CLAIM OF PRIORITY

This application is a divisional of U.S. patent application Ser. No. 14/541,228, filed Nov. 14, 2014, which claims benefit of priority of U.S. Provisional Application Ser. No. 62/024,147 entitled “PACKAGE-ON-PACKAGE OPTIONS WITH MULTIPLE LAYER 3-D STACKING” filed Jul. 14, 2014, the contents of which are incorporated by reference herein in their entirety and for all purposes.

### BACKGROUND

1. Technical Field

Embodiments described herein relate to semiconductor packaging and methods for packaging semiconductor devices. More particularly, some embodiments disclosed herein relate to a package-on-package (“PoP”) using three-dimensional stacking to decrease footprint of the PoP and associated main memory.

2. Description of the Related Art

Package-on-package (“PoP”) technology has become increasingly popular as the demand for lower cost, higher performance, increased integrated circuit density, and increased package density continues in the semiconductor industry. As the push for smaller and smaller packages increases, the integration of die and package (e.g., “pre-stacking” or the integration of system on a chip (“SoC”) technology with memory technology) allows for thinner packages. Such pre-stacking has become a critical component for thin and fine pitch PoP packages. FIG. 1 depicts an embodiment of a current package on package format 100 including local memory modules 110 coupled to the PoP. Typically a main memory module 120 for a device may be positioned remotely from the package 100. Package 100 may employ main memory module 120; however, positioning the main memory module remotely is inefficient because it increases communication time between the main memory module and the package 100 and decreases the amount of room available for other electronic components.

### SUMMARY

In some embodiments, a semiconductor device package on package assembly may include a first package, a second package, and a third package. The first package may include a first surface, a second surface substantially opposite the first surface, a first die, and a first set of electrical conductors. The first set of electrical conductors may be coupled to the first surface. The first set of electrical conductors may be configured to electrically connect the package on package assembly. The second package may include a third surface and a fourth surface substantially opposite the third surface, and a local memory module. The third surface may be coupled to the second surface. The first package may be electrically coupled to the second package. The third package may include a fifth surface and a sixth surface substantially opposite the fifth surface, and a main memory module. The fifth surface may be coupled to the fourth surface. The third package may be electrically coupled to the first package and/or the second package.

In some embodiments, the local memory may include a cache. In some embodiments, the local memory module may function to manage a first set of data. The main memory may function to manage a second set of data greater in size than the first set of data. The second set of data may include at least the first set of data or a version of the first set of data.

### BRIEF DESCRIPTION OF THE DRAWINGS

The following detailed description makes reference to the accompanying drawings, which are now briefly described.

FIG. 1 depicts an embodiment of a current package on package format including a local memory with a main memory positioned remotely from the package on package.

FIGS. 2A-B depict an embodiment of a package on package format including a local memory (e.g., wide I/O memory module) and a main memory (e.g., double data rate dynamic random-access memory (I)DR DRAM)) stacked three-dimensionally and detailing the electrical connectivity between the packages.

FIGS. 3A-B depict an embodiment of a package on package format including a local memory (e.g., wide I/O memory module) and a main memory (e.g., wide I/O memory module) stacked three-dimensionally and detailing the electrical connectivity between the packages.

FIGS. 4A-B depict an embodiment of a package on package format including a local memory (e.g., wide I/O memory module) and a main memory (e.g., wide I/O memory module) stacked three-dimensionally and detailing the electrical connectivity between the packages.

FIGS. 5A-B depict an embodiment of a package on package format including a local memory (e.g., wide I/O memory module) and a main memory (e.g., wide I/O memory module) coupled to a single substrate and detailing the electrical connectivity between the packages.

FIGS. 6A-B depict an embodiment of a package on package format including a local memory (e.g., DDR memory module) and a main memory (e.g., DDR memory module) stacked three-dimensionally and detailing the electrical connectivity between the packages.

Specific embodiments are shown by way of example in the drawings and will be described herein in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

The headings used herein are for organizational purposes only and are not meant to be used to limit the scope of the description. As used throughout this application, the word “may” is used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third die electrically connected to the module substrate” does not preclude scenarios in which a “fourth die electrically connected to the module substrate” is connected prior to the third die, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. §112 paragraph (f), interpretation for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF EMBODIMENTS

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

In today's world space for components in electrical device is at a premium due to manufacturers desiring to include more and more components in the electrical device to provide more computing power and/or more functions without increasing the overall size of the electronic device. In many instances manufacturers are attempting to decrease the size of electrical devices even if they are not trying to provide more computing power and/or more functions further prompting the desire to reduce and/or combine components.

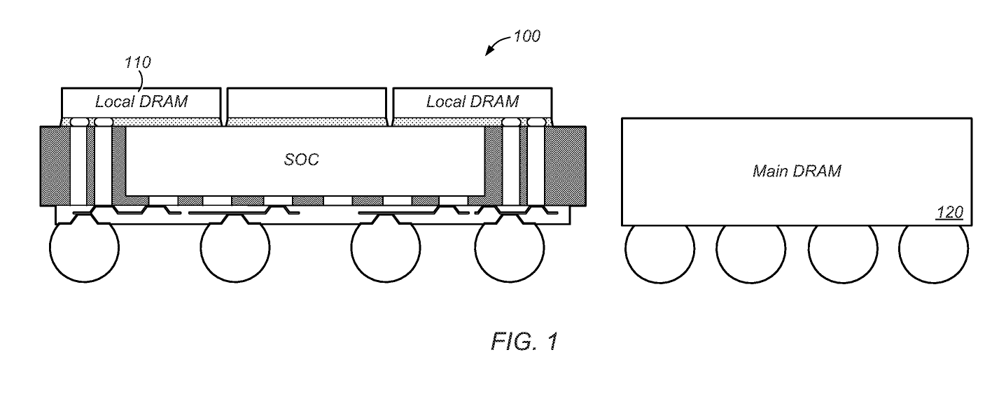

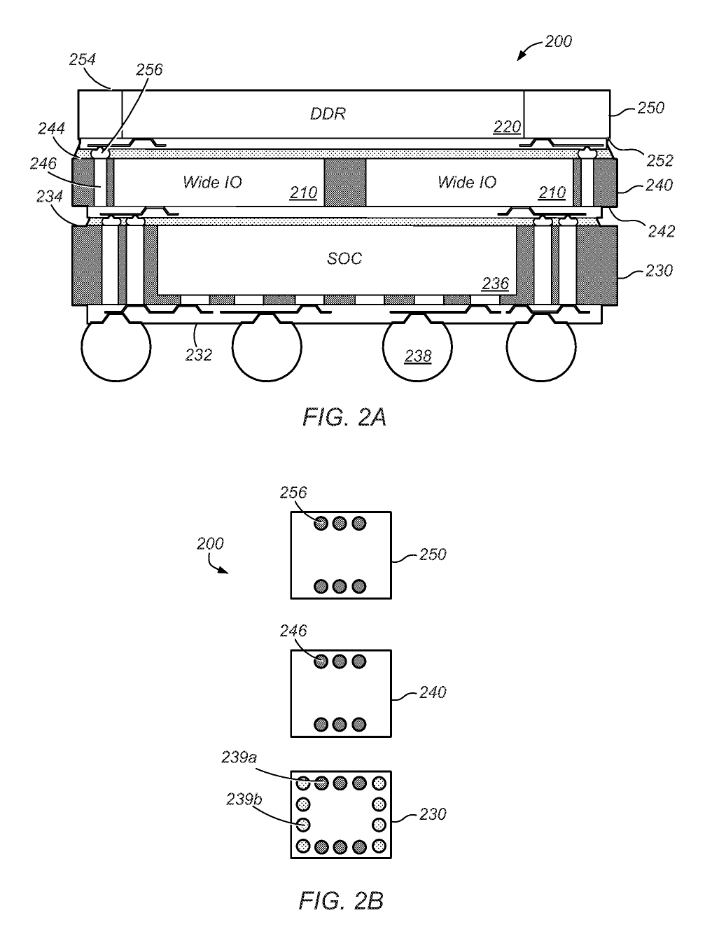

FIG. 1 depicts an embodiment of a current package on package format 100 including local memory modules 110 coupled to the PoP. Typically a main memory module 120 for a device may be positioned remotely from the package 100. It would be advantageous to stack the main memory module 120 three-dimensionally on top of package 100. FIG. 2A depicts an embodiment of a package on package assembly 200 including a local memory 210 (e.g., wide I/O memory module) and a main memory 220 (e.g., double data rate dynamic random-access memory (DDR DRAM)) stacked three-dimensionally.

In some embodiments, a semiconductor device package on package assembly 200 may include a first package 230, a second package 240, and a third package 250. The first package may include a first surface 232, a second surface 234 substantially opposite the first surface 232, a first die 236, and a first set of electrical conductors 238. The first set of electrical conductors 238 may be coupled to the first surface 232. The first set of electrical conductors 238 may be configured to electrically connect the package on package assembly 200. The second package 240 may include a third surface 242 and a fourth surface 244 substantially opposite the third surface 242, and a local memory module 210. In some embodiments, the local memory 210 may be used as memory cache. The third surface 242 may be coupled to the second surface 234. The first package 230 may be electrically coupled to the second package 240. In some embodiments, the first package 230 and the second package 240 may be formed in a wafer level package on package.

In some embodiments, the local memory may include a cache. In some embodiments, the local memory module may function to manage a first set of data. The main memory may function to manage a second set of data greater in size than the first set of data. The second set of data may include at least the first set of data or a version of the first set of data. In some embodiments, the local memory and the main memory may include different types of memory (e.g., wide I/O, LPDDR, DDR). In some embodiments, the local memory may function to manage data associated with the assembly. The main memory may function to manage at least data associated with a system to which the assembly is electrically coupled. In some embodiments, the local memory has a lower latency than the main memory. In some embodiments, the local memory has a greater rate of data transfer than the main memory.

In some embodiments, the local memory module 210 may include wide I/O memory module. In some embodiments, it is desirable to increase memory bandwidth using an integrated solution. In one embodiment, wide I/O memory may be used. Described herein are embodiments using packaging architectures capable of employing the use of standard wide I/O memory modules without further reconfiguration of the module. In some embodiments, a standard wide I/O memory module may comprise a set of electrical conductors substantially centered within the memory module away from the edges. In some embodiments, a standard wide I/O memory module may comprise a set of electrical conductors configured in at least four channels. In some embodiments, reconfigured wide I/O memory modules may include any design, structure, process change to the existing memory die/wafer to in order to change the memory modules pad (or bump) locations and/or pitch, number of channels, and/or die size. In some embodiments, wide I/O herein may refer to wide I/O, or wide 1/02, or wide 1/03 as defined by JEDEC solid state technology association standards and publications or any other future configuration of wide I/O.

In some embodiments, the third package 250 may include a fifth surface 252 and a sixth surface 254 substantially opposite the fifth surface 252, and a main memory module 220. The fifth surface 252 may be coupled to the fourth surface 244. The third package 250 may be electrically coupled to the first package 230 and/or the second package 240. In some embodiments, the main memory module 220 may include a DDR DRAM. The main memory module 220 may be formed in a Fanout Wafer Level Package (FOWLP).

In some embodiments, the local memory 210 and the main memory 220 may include different controllers. FIG. 2B depicts an embodiment of a package on package assembly 200 detailing the electrical connectivity between the packages. The local memory 210 and the main memory 220 may include different controllers due to the use of different electrical connector technology. For example, the main memory 220 may be connected through electrical connectors 256 (e.g., solder balls) and the local memory 210 may be connected through vias 246. Such a configuration requires vias 239a-b on all sides of the first package 230 in order to electrically connect with the second and the third packages 240 and 250.

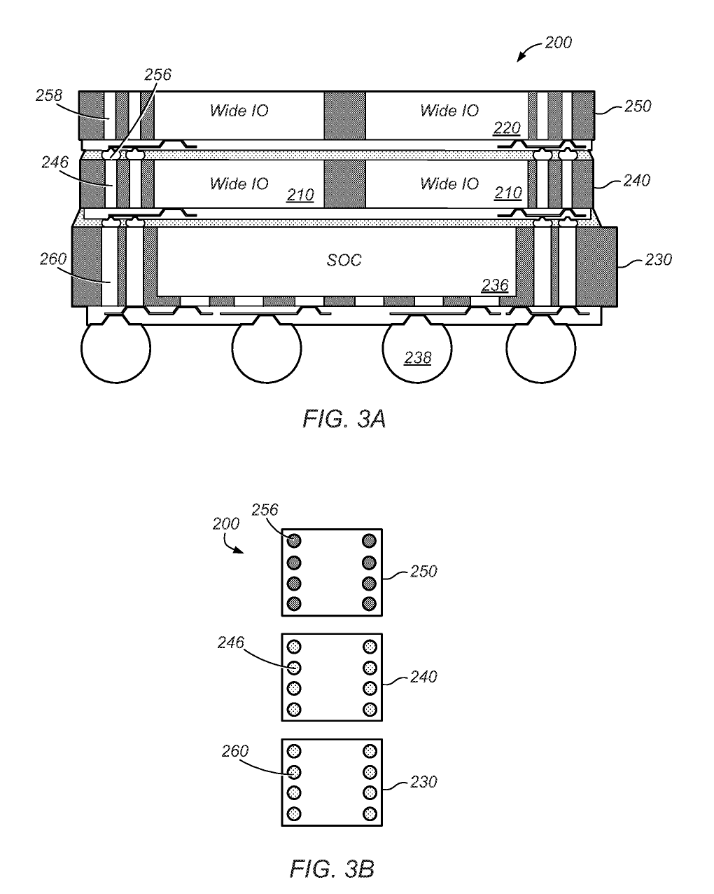

FIG. 3A depicts an embodiment of a package on package format 200 including a local memory 210 (e.g., wide I/O memory module) and a main memory 220 (e.g., wide I/O memory module) stacked three-dimensionally and detailing the electrical connectivity between the packages. In some embodiments, the packages 230-250 may be formed in a wafer level package on package format. Such an embodiment has several advantages including fewer different components facilitating manufacturing. Due to the third package 250 including vias 258 the package 200 may be expandable further in upwards in the third dimension.

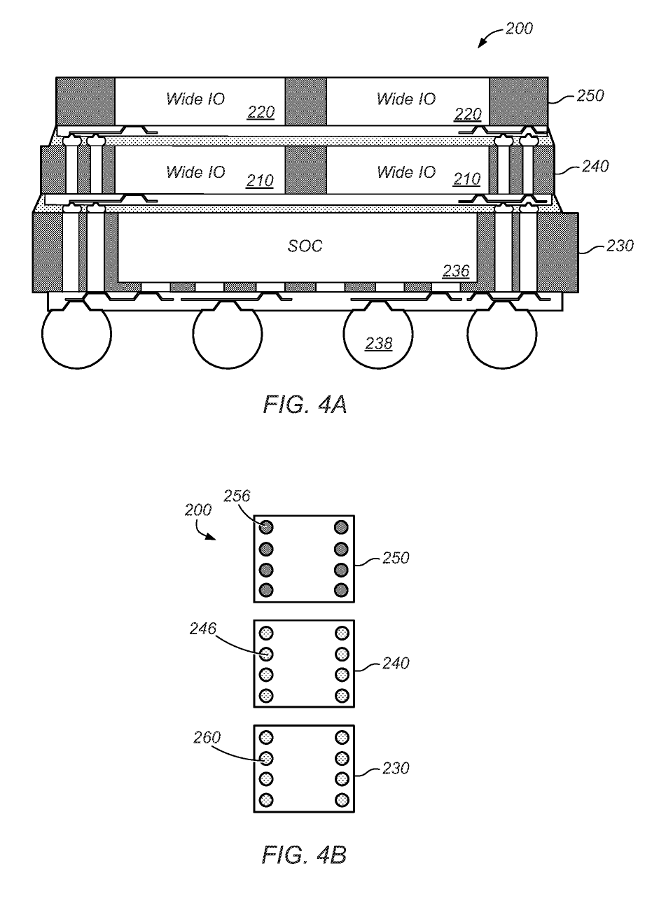

In some embodiments, the package 200 may not be expandable due to the absence of vias in the third package 250. FIG. 4A depicts an embodiment of a package on package format 200 including a local memory 210 (e.g., wide I/O memory module) and a main memory 220 (e.g., wide I/O memory module) stacked three-dimensionally. However, due to the second package 240 and the third package 250 not being identical, manufacturing will be more complicated relative to the embodiment depicted in FIG. 3A.

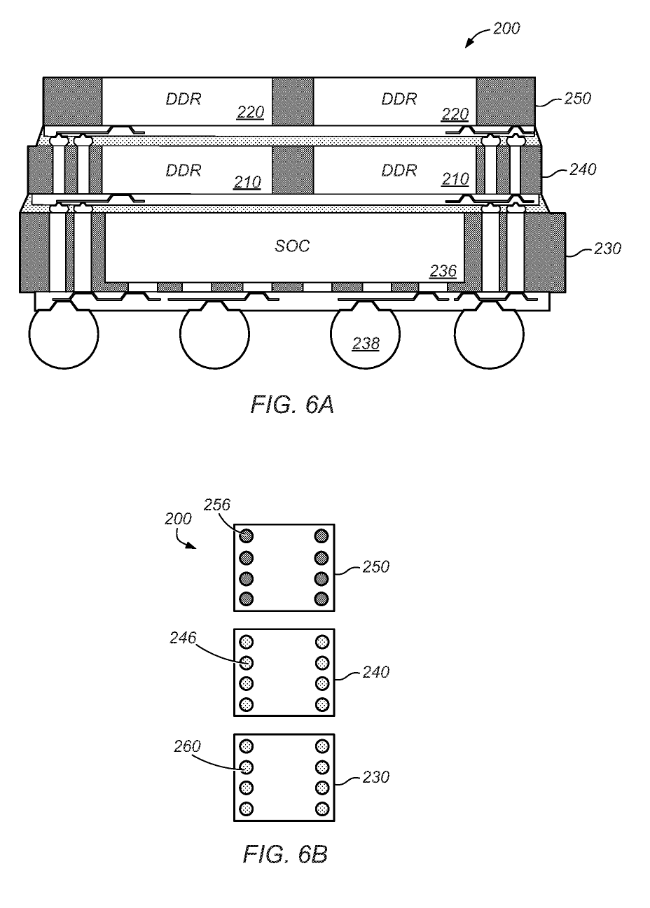

In some embodiments, DDR memory may be used instead of wide I/O memory as depicted in the embodiment in FIG. 4A. FIG. 6A depicts an embodiment of a package on package format 200 including a local memory 210 (e.g., DDR memory module) and a main memory 220 (e.g., DDR memory module) stacked three-dimensionally. DDR memory modules may include low power DDR (LPDDR), DDR1, DDR2, DDR3, or any future standardized memory modules.

FIGS. 3B and 4B and 6B depict embodiments of a package on package assembly 200 detailing the electrical connectivity between the packages. The local memory 210 and the main memory 220 may include different controllers due to the use of different electrical connector technology. For example, the main memory 220 may be connected through electrical connectors 256 (e.g., solder balls) and through vias 246 of the second package 240. The second package 240 may be electrically connected through vias 260 of the first package 230 to electrical conductors 238.

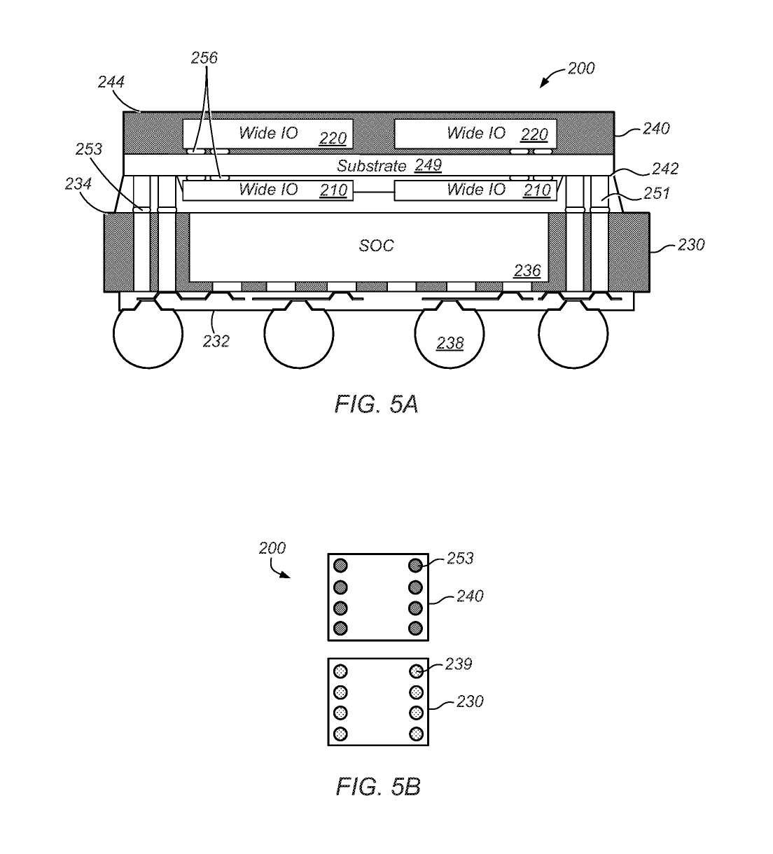

FIG. 5A depicts an embodiment of a package on package format 200 including a local memory 210 (e.g., wide I/O memory module) and a main memory 220 (e.g., wide I/O memory module) coupled to a single substrate. In some embodiments, a semiconductor device package on package assembly 200 may include a first package 230 and a second package 240. The first package may include a first surface 232, a second surface 234 substantially opposite the first surface 232, a first die 236, and a first set of electrical conductors 238. The first set of electrical conductors 238 may be coupled to the first surface 232. The first set of electrical conductors 238 may be configured to electrically connect the package on package assembly 200. The second package 240 may include a third surface 242 and a fourth surface 244 substantially opposite the third surface 242, and a local memory module 210. The local memory module 210 may be coupled to a substrate 249. The second package 240 may include main memory 220. The main memory may be coupled to the substrate 249. The main memory and the local memory may be coupled to opposing sides of the substrate 249. In some embodiments, the local memory 210 may include a cache or may be used as memory cache. The third surface 242 may be coupled to the second surface 234. The first package 230 may be electrically coupled to the second package 240. In some embodiments, the first package 230 and the second package 240 may be formed in a wafer level package on package.

FIG. 5B depict an embodiment of a package on package assembly 200 detailing the electrical connectivity between the packages. For example, the main memory 220 and the local memory may be connected through electrical connectors 256 (e.g., solder balls) and through electrical wiring (traces) in substrate 249. Electrical connectors 251 (e.g., copper columns) may couple the second package 240 to the first package 230 using electrical connectors 253 (e.g., solder tips). Vias 239 of the first package 230 may electrically couple the first package 230 to the second package 240.

In some embodiments, the substrate 249 may include an RDL. Substrate 249 may include materials such as, but not limited to, PI (polyimide), PBO (polybenzoxazole), BCB (benzocyclobutene), and WPRs (wafer photo resists such as novolak resins and poly(hydroxystyrene) (PHS) available commercially under the trade name WPR including WPR-1020, WPR-1050, and WPR-1201 (WPR is a registered trademark of JSR Corporation, Tokyo, Japan)). Substrate 249 may be formed using techniques known in the art (e.g., techniques used for polymer deposition).

In some embodiments, the package on package assembly may include a plurality of wires (e.g., positioned in substrate 249). The plurality of wires may be positioned in the substrate 249. The substrate 249 may include one or more layers of wires or routing. In certain embodiments, the substrate 249 may include two or more layers of wiring or routing. The routing may be, for example, copper wiring or another suitable electrical conductor wiring. A thickness of the substrate 249 may depend on the number of layers of routing in the substrate. For example, each layer of routing may be between about 5 μm and about 10 μm in thickness. In certain embodiments, substrate 249 may have a thickness of at least about 5 μm and at most about 150 μm.

In some embodiments, the main memory 220 may be coupled to substrate 249 first and then encapsulated. The local memory 210 may be coupled to an opposing side of the substrate 249.

Numerous variations and modifications will become apparent to those skilled in the art once the above disclosure is fully appreciated. It is intended that the following claims be interpreted to embrace all such variations and modifications.

What is claimed is:

1. A semiconductor device package on package assembly, comprising:
a first package comprising a first surface, a second surface substantially opposite the first surface, a first die, and a first set of electrical conductors coupled to the first surface and configured to electrically connect the package on package assembly;
a second package comprising a third surface and a fourth surface substantially opposite the third surface, and a local memory module, wherein the third surface is coupled to the second surface, and wherein the first package is electrically coupled to the second package; and
a third package comprising a fifth surface and a sixth surface substantially opposite the fifth surface, and a main memory module, wherein the fifth surface is coupled to the fourth surface, and wherein the third package is electrically coupled to the first package and/or the second package;
wherein the local memory module is a cache.

2. The assembly of claim 1, wherein the local memory and the main memory comprise different types of memory.

3. The assembly of claim 1, wherein the local memory has a lower latency than the main memory.

4. The assembly of claim 1, wherein the local memory has a greater rate of data transfer than the main memory.

5. The assembly of claim 1, wherein the local memory module comprises, during use, a first set of data and the main memory comprises, during use, a second set of data greater in size than the first set of data, and wherein the second set of data comprises, during use, at least the first set of data or a version of the first set of data.

6. The assembly of claim 1, further comprising:
a first controller for a data flow to and from the local memory; and
a second controller for a data flow to and from the main memory, wherein the second controller is different from the first controller.

7. The assembly of claim 1, wherein the first controller is associated with a first plurality of electrical connectors and the second controller is associated with a second plurality of electrical connectors, and wherein the first plurality of electrical connectors are different from the second plurality of electrical connectors.

8. A semiconductor device package on package assembly, comprising:
a first package comprising a first surface, a second surface substantially opposite the first surface, a first die, and a first set of electrical conductors coupled to the first surface and configured to electrically connect the package on package assembly;
a second package comprising a third surface and a fourth surface substantially opposite the third surface, and a local memory module, wherein the third surface is coupled to the second surface, and wherein the first package is electrically coupled to the second package; and
a third package comprising a fifth surface and a sixth surface substantially opposite the fifth surface, and a main memory module, wherein the fifth surface is coupled to the fourth surface, and wherein the third package is electrically coupled to the first package and/or the second package;
wherein the local memory module has a lower latency than the main memory.

9. The assembly of claim 6, wherein the local memory and the main memory comprise different types of memory.

10. The assembly of claim 6, wherein the local memory comprises a cache.

11. The assembly of claim 6, wherein the local memory has a greater rate of data transfer than the main memory.

12. The assembly of claim 6, wherein the local memory module comprises, during use, a first set of data and the main memory comprises, during use, a second set of data greater in size than the first set of data, and wherein the second set of data comprises, during use, at least the first set of data or a version of the first set of data.

13. The assembly of claim 6, further comprising:
a first controller for a data flow to and from the local memory; and
a second controller for a data flow to and from the main memory, wherein the second controller is different from the first controller.

14. The assembly of claim 6, wherein the first controller is associated with a first plurality of electrical connectors and the second controller is associated with a second plurality of electrical connectors, and wherein the first plurality of electrical connectors are different from the second plurality of electrical connectors.

15. A semiconductor device package on package assembly, comprising:
a first package comprising a first surface, a second surface substantially opposite the first surface, a first die, and a first set of electrical conductors coupled to the first surface and configured to electrically connect the package on package assembly;
a second package comprising a third surface and a fourth surface substantially opposite the third surface, and a local memory module, wherein the third surface is coupled to the second surface, and wherein the first package is electrically coupled to the second package; and
a third package comprising a fifth surface and a sixth surface substantially opposite the fifth surface, and a main memory module, wherein the fifth surface is coupled to the fourth surface, and wherein the third package is electrically coupled to the first package and/or the second package;
wherein the local memory module has a greater rate of data transfer than the main memory.

16. The assembly of claim 11, wherein the local memory and the main memory comprise different types of memory.

17. The assembly of claim 11, wherein the local memory comprises a cache.

18. The assembly of claim 11, wherein the local memory has a lower latency than the main memory.

19. The assembly of claim 11, wherein the local memory module comprises, during use, a first set of data and the main memory comprises, during use, a second set of data greater in size than the first set of data, and wherein the second set of data comprises, during use, at least the first set of data or a version of the first set of data.

20. The assembly of claim 11, further comprising:
a first controller for a data flow to and from the local memory; and
a second controller for a data flow to and from the main memory, wherein the second controller is different from the first controller.
